(19) United States
(12) Patent Application Publication
(10) Pub. No.: US 2025/0308922 A1
(43) Pub. Date: Oct. 2, 2025

(54) SUBSTRATE PROCESSING METHOD AND SUBSTRATE PROCESSING APPARATUS

(71) Applicant: PSK INC., Gyeonggi-do (KR)

(72) Inventors: A Ram KIM, Gyeonggi-do (KR); Min Jae JEONG, Gyeonggi-do (KR)

(21) Appl. No.: 19/097,650

(22) Filed: Apr. 1, 2025

(30) Foreign Application Priority Data
Apr. 2, 2024 (KR) 10-2024-0044903

(51) Int. Cl. H01L 21/311; H01J 37/32

(52) U.S. Cl. CPC H01L 21/31116; H01J 37/32357; H01J 37/32715; H01J 2237/0044; H01J 2237/2007; H01J 2237/334

(57) ABSTRACT

The inventive concept provides a method of processing a substrate. The method of processing a substrate may include a substrate processing operation of supplying first plasma generated in a plasma generation space through a baffle assembly into a treatment space, and processing a substrate supported on a support unit within the treatment space by using the first plasma; and a neutralizing operation of, after the substrate processing operation, while the substrate is supported on the support unit, supplying second plasma generated in the plasma generation space through the baffle assembly into the treatment space to remove residual charges on the substrate.

### CROSS-REFERENCE TO RELATED APPLICATIONS

This application claims priority to and the benefit of Korean Patent Application No. 10-2024-0044903 filed in the Korean Intellectual Property Office on Apr. 2, 2024, the entire contents of which are incorporated herein by reference.

### TECHNICAL FIELD

The present invention relates to a substrate processing method and a substrate processing apparatus, and more particularly to a method and apparatus for processing a substrate by using plasma.

### BACKGROUND ART

Plasma refers to an ionized gas state formed of ions, radicals, electrons, and the like, and is generated by a very high temperature, strong electric fields, or RF electromagnetic fields. Semiconductor device manufacturing processes include the ashing or etching process, which uses plasma to remove films from substrates, such as wafers.

In removing the film on the substrate, among the ions, electrons, and radicals contained in the plasma, radicals may be utilized mainly. In this case, a grounded baffle is provided between the plasma generation space where the plasma is generated and the treatment space where the substrate is treated, and radicals in the plasma are supplied into the treatment space through holes formed in the baffle.

The power source also applies an RF signal to the lower electrodes of the substrate support unit that supports the substrate, creating an electric field in the treatment space. After the plasma treatment of the substrate is finished, strong attraction force is formed between the substrate and the lower electrode due to the accumulation of negative charges on the surface of the substrate. When the substrate is forcibly lifted in this state, the substrate may be damaged due to the attraction between the substrate and the substrate support unit.

### SUMMARY OF THE INVENTION

The present invention has been made in an effort to provide a substrate processing method and a substrate processing apparatus which are capable of efficiently processing a substrate.

The present invention has also been made in an effort to provide a substrate processing method and a substrate processing apparatus which are capable of neutralizing a substrate by discharging an accumulated charge on the substrate after processing the substrate with plasma.

The present invention has also been made in an effort to provide a substrate processing method and a substrate processing apparatus which are capable of controlling the proportion of ions contained in plasma passing through a baffle assembly by varying a hole pattern and hole size of the baffle assembly.

The present invention has also been made in an effort to provide a substrate processing method and a substrate processing apparatus which are capable of minimizing damage to a substrate when the substrate is lifted from a substrate support unit.

The inventive concept provides a method of processing a substrate. The method of processing a substrate may include a substrate processing operation of supplying first plasma generated in a plasma generation space through a baffle assembly into a treatment space, and processing a substrate supported on a support unit within the treatment space by using the first plasma; and a neutralizing operation of, after the substrate processing operation, while the substrate is still supported on the support unit, supplying second plasma generated in the plasma generation space through the baffle assembly into the treatment space to remove residual charges on the substrate.

According to the exemplary embodiment, a proportion of ions to radicals in the second plasma supplied into the treatment space may be provided higher than a proportion of ions to radicals in the first plasma supplied into the treatment space.

According to the exemplary embodiment, the baffle assembly may include an upper baffle formed with a plurality of upper holes penetrating in an upward and downward direction; and a lower baffle stacked with the upper baffle and formed with a plurality of lower holes penetrating in the upward and downward direction, and in the substrate processing operation, the upper hole and the lower hole are maintained in a first degree of overlap when viewed from above, in the neutralizing operation, the upper hole and the lower hole are maintained in a second degree of overlap when viewed from above, and the second degree of overlap may be a higher degree of overlap of the upper hole and the lower hole compared to the first degree of overlap.

According to the exemplary embodiment, the degree of overlap of the upper hole and the lower hole may be switched between the first degree of overlap and the second degree of overlap by changing a relative position of the upper baffle or the lower baffle.

According to the exemplary embodiment, the relative position of the upper baffle or the lower baffle may be changed by rotating at least one of the upper baffle and the lower baffle.

According to the exemplary embodiment, the substrate processing operation may be a process of removing a thin film on the substrate by using plasma.

According to the exemplary embodiment, the thin film may be a hard mask.

According to the exemplary embodiment, the support unit may include an electrostatic chuck, the method further comprises: a loading operation of placing the substrate onto the support unit prior to the substrate processing operation; and an unloading operation of lifting the substrate from the support unit after the neutralizing operation, and the loading operation may be an operation of chucking the substrate onto the electrostatic chuck, and the unloading operation may be an operation of dechucking the substrate from the electrostatic chuck.

According to the exemplary embodiment, the support unit further may include a high frequency power source applying high frequency power, in the substrate processing operation, the high frequency power source generates plasma in the treatment space, and after the substrate processing operation ends, the high frequency power source may be switched off and the neutralizing operation may be performed.

According to the exemplary embodiment, the plasma generating space may be supplied with treatment gas to generate plasma, and the treatment gas supplied to the plasma generation space in the substrate processing operation and in the neutralizing operation may be the same gas.

The inventive concept provides a method of processing a substrate. The method of processing a substrate may include a loading operation of placing a substrate onto a support unit in a treatment space; a substrate processing operation of, after the loading operation, supplying first plasma generated in the plasma generation space through a baffle assembly into the treatment space and treat the substrate with the first plasma; a neutralizing operation of, after the substrate processing operation, while the substrate is supported on the support unit, supplying second plasma generated in the plasma generation space through the baffle assembly into the treatment space to remove residual charges on the substrate; and an unloading operation of, after the neutralizing operation, lifting the substrate from the support unit, wherein a proportion of ions to radicals in the second plasma supplied into the treatment space may be provided higher than a proportion of ions to radicals in the first plasma supplied into the treatment space.

According to the exemplary embodiment, the support unit further may include a high frequency power source applying high frequency power, in the substrate processing operation, the high frequency power source generates plasma in the treatment space, and after the substrate processing operation ends, the high frequency power source may be switched off and the neutralizing operation may be performed.

According to the exemplary embodiment, the baffle assembly may include: an upper baffle formed with a plurality of upper holes penetrating in an upward and downward direction; and a lower baffle stacked with the upper baffle and formed with a plurality of lower holes penetrating in the upward and downward direction, and in the substrate processing operation, the upper holes and the lower holes are maintained in a first degree of overlap when viewed from above, in the neutralizing operation, the upper hole and the lower hole are maintained in a second degree of overlap when viewed from above, and the second degree of overlap may be a higher degree of overlap of the upper hole and the lower hole compared to the first degree of overlap.

According to the exemplary embodiment, the degree of overlap of the upper hole and the lower hole may be switched between the first degree of overlap and the second degree of overlap by changing a relative position of the upper baffle or the lower baffle.

According to the exemplary embodiment, the relative position of the upper baffle or the lower baffle may be changed by rotating at least one of the upper baffle or the lower baffle.

The inventive concept provides an apparatus for processing a substrate. The substrate processing apparatus may include a treatment chamber having a treatment space for processing a substrate therein; a support unit for supporting a substrate in the treatment space; a plasma generation chamber provided outside the treatment chamber and having a plasma generation space for generating plasma from treatment gas; a baffle assembly disposed between the treatment space and the plasma generation space; and a controller, wherein the baffle assembly may include: an upper baffle formed with a plurality of upper holes penetrating in an upward and downward direction; a lower baffle stacked with the upper baffle and formed with a plurality of lower holes penetrating in the upward and downward direction; and a drive unit for changing a relative position of the upper baffle and the lower baffle, and the controller controls the drive unit to sequentially perform a substrate processing operation of processing the substrate by supplying first plasma into the treatment space in a state where the upper hole and the lower hole are maintained in a first degree of overlap when viewed from above, and a neutralizing operation of, after the substrate processing operation, supplying second plasma into the treatment space in a state where the upper hole and the lower hole are maintained in a second degree of overlap to remove a residual charge on the substrate, and the second degree of overlap may be a higher degree of overlap of the upper hole and the lower hole compared to the first degree of overlap.

According to the exemplary embodiment, the drive unit may rotate at least one of the upper baffle and the lower baffle to adjust a hole pattern and a hole size of the baffle assembly.

According to the exemplary embodiment, the apparatus may further include a high frequency power source for applying high frequency power to the support unit.

According to the exemplary embodiment, in the substrate processing operation, the hole size of the baffle assembly may be smaller than a size of a sheath around the hole of the baffle assembly.

According to the exemplary embodiment, in the neutralizing operation, the controller may adjust the size of the hole of the baffle assembly to be greater than a size of a sheath around the hole in the baffle assembly.

According to the exemplary embodiment of the present invention, it is possible to efficiently treat the substrate.

Furthermore, according to the exemplary embodiment of the present invention, after processing a substrate with plasma, the substrate may be neutralized by rapidly discharging the charge accumulated on the substrate.

Furthermore, according to the exemplary embodiment of the present invention, the proportion of ions contained in the plasma passing through the baffle assembly may be controlled by varying the hole pattern and hole size of the baffle assembly.

Furthermore, according to the exemplary embodiment of the present invention, damage to the substrate may be minimized when lifting the substrate from the substrate support unit.

### BRIEF DESCRIPTION OF THE DRAWINGS

FIG. 1 is a diagram illustrating a photoresist film formed on a substrate.

FIG. 2 is a diagram illustrating a hardmask film formed on a substrate.

FIG. 3 is a diagram illustrating a substrate processing apparatus according to an exemplary embodiment of the present invention.

FIG. 4 is a flow chart illustrating an exemplary embodiment of a method of processing a substrate using the substrate processing apparatus of FIG. 3.

FIG. 5 is a diagram schematically illustrating the case where the substrate processing apparatus of FIG. 3 performs the substrate processing operation of FIG. 4.

FIG. 6 is an enlarged view of a baffle assembly of FIG. 5.

FIGS. 7 to 9 are diagrams schematically illustrating what the substrate processing apparatus of FIG. 3 looks like when performing the neutering operation of FIG. 4.

FIG. 10 is an enlarged view of the baffle assembly of FIG. 9.

FIG. 11 is a diagram schematically illustrating the case where the substrate processing apparatus of FIG. 3 performs an unloading operation of FIG. 4.

FIGS. 12 to 14 are diagrams illustrating a substrate processing apparatus according to another exemplary embodiment of the present invention.

FIG. 15 is a diagram illustrating a substrate processing apparatus according to another exemplary embodiment of the present invention.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

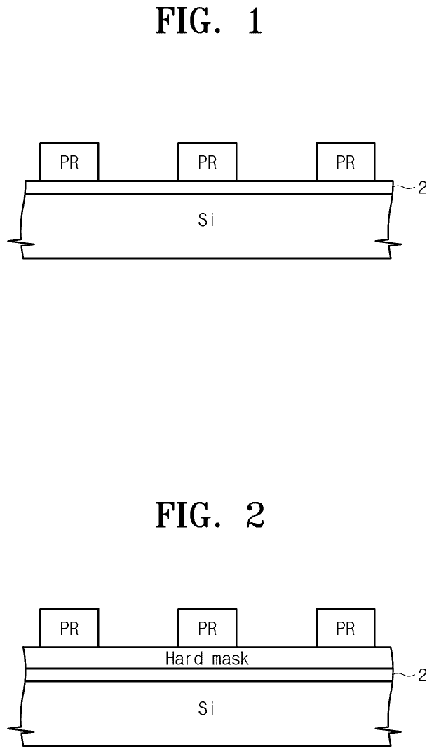

Hereinafter, with reference to FIGS. 1 to 8, a substrate processing apparatus and a substrate processing method according to an exemplary embodiment of the present invention will be described in detail. A substrate W described hereinafter may be a wafer. Processing the substrate W may mean not only processing the substrate W but also removing a film or the like formed on the substrate W.

In one example, the substrate processing apparatus may etch a thin film on the substrate W. The thin film may be of various types, including polysilicon films, silicon oxide films, and silicon nitride films. Furthermore, the thin film may be a natural oxide film or a chemically generated oxide film.

FIG. 1 is a diagram illustrating a photoresist film formed on a thin film 2 on a substrate, and FIG. 2 is a diagram illustrating a hardmask film formed on the thin film 2 on the substrate.

A substrate to be treated as described herein may have a first film (e.g., a photoresist thin film) formed on the substrate, as illustrated in FIG. 1, and a second film (e.g., a hardmask thin film) formed on the substrate, as illustrated in FIG. 2. In FIG. 2, both the first film (photoresist thin film) and the second film (hardmask thin film) are formed on the substrate, but in some cases, only the second film (hardmask thin film) between the first film (photoresist thin film) and the second film (hardmask thin film) may be formed on the substrate. The hardmask film may be an Amorphous Carbon Layer (ACL). The Amorphous Carbon Layer (ACL) may be a Boron doped Amorphous Carbon Layer (BACL).

The substrate processing method described herein may be a manufacturing method for manufacturing a semiconductor device. The substrate processing method may include at least one process among a number of processes required to manufacture a semiconductor device.

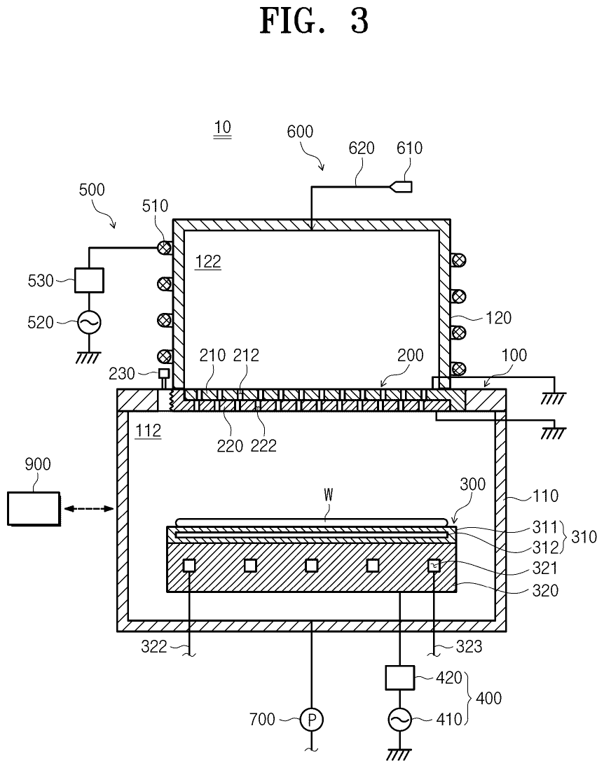

FIG. 3 is a diagram illustrating a substrate processing apparatus according to an exemplary embodiment of the present invention.

Referring to FIG. 3, a substrate processing apparatus 10 according to an exemplary embodiment of the present invention may include a chamber 100, a baffle assembly 200, a support unit 300, a lower power unit 400, a source unit 500, a gas supply unit 600, an exhaust device 700, an ionization device 800, and a controller 900.

The chamber 100 may include a treatment chamber 110 defining a treatment space 112, and a plasma generation chamber 120 defining a plasma generation space 122. The plasma generation chamber 120 may be provided outside of the treatment chamber 110. The treatment chamber 110 and the plasma generation chamber 120 may be arranged along an up-down direction. The treatment chamber 110 may be installed below the plasma generation chamber 120. In the treatment space 112, a treatment process for the substrate W may be performed, and in the plasma generation space 122, the source unit 500 which is to be described below may generate plasma from process gas supplied by the gas supply unit 600 described later. The treatment chamber 110 may be grounded. The current in the electric field formed by the bias power applied by the lower power unit 400, described later, may flow through the treatment chamber 110 to ground.

The treatment chamber 110 may have an inlet/outlet not illustrated. The substrate W may be brought into, or taken out of, the treatment chamber 112 via the inlet/outlet. inlet/outlet may be selectively opened and closed by a door.

The plasma generation chamber 120 may provide the plasma generation space 122 in which the plasma P described hereinafter is generated. Although plasma P may also be generated in the treatment space 112 by the lower power unit 400, the plasma P provided for processing the substrate W may be generated in the plasma generation space 122.

The plasma generation space 122 may be in fluid communication with the treatment space 112. The plasma P generated in the plasma generation space 122 may flow from the plasma generation space 122 to the treatment space 112.

The gas supply unit 600 described later may supply the process gas to the plasma generation space 122, and the source unit 400 may excite the process gas to generate the plasma P.

The baffle assembly 200 may be installed between the treatment space 112 and the plasma generation space 122. The baffle assembly 200 may be installed between the treatment space 112 and the plasma generation space 122 to compartmentalize the two spaces. The baffle assembly 200 may define the treatment space 112 together with the treatment chamber 110. Further, the baffle assembly 200 may define the plasma generation space 122 in conjunction with the plasma generation chamber 120.

The baffle assembly 200 includes an upper baffle 210 and a lower baffle 220, and a drive unit 230. The upper baffle 210 and the lower baffle 220 may each have a plate shape. The upper baffle 210 may have a plurality of top holes 212 formed through the upper baffle 210 in an upward and downward direction. The lower baffle 220 may have a plurality of lower holes 222 formed through the lower baffle 220 in an upward and downward direction. The upper baffle 210 may be stacked on top of the lower baffle 220, but may be provided spaced apart by a predetermined distance such that their relative positions may be changed by the drive unit 230 described later.

The treatment space 112 and the plasma generation space 122 may be in communication with each other via the plurality of holes 212, 222 formed in the upper baffle 210 and the lower baffle 220 of the baffle assembly 200. Plasma generated in the plasma generation space 122 may enter the treatment space 112 through the holes 212, 222 formed in the baffle assembly 200. That is, plasma generated in the plasma generation space 122 may enter the treatment space 112 by sequentially passing through the upper hole 212 of the upper baffle 210 and the lower hole 222 of the lower baffle 220.

The baffle assembly 200 may be grounded. The upper baffle 210 and the lower baffle 220 may each be grounded, and may be electrically grounded to the grounded chamber 100.

The plasma generated in the plasma generation space 122 may include ions and radicals. In the process in which the plasma generated in the plasma generation space 122 enters the treatment space 112 through the holes 212, 222 formed in the upper baffle 210 and the lower baffle 220, at least some of the ions contained in the plasma may be trapped by the grounded baffle assembly 200.

The upper baffle 210 and the lower baffle 220 may be made of a material including metal. The upper baffle 210 and the lower baffle 220 may be made of a conductive material.

The upper hole 212 formed in the upper baffle 210 and the lower hole 222 formed in the lower baffle 220 may be spaced apart at a certain distance along the circumferential direction of the upper baffle 210 and the lower baffle 220, respectively.

The upper hole 212 formed in the upper baffle 210 and the lower hole 222 formed in the lower baffle 220 may have a generally circular shape. The diameters of the holes 212, 222 may be varied depending on the proportion of radicals that need to be transferred to the substrate W, and the like. In contrast, the holes 212, 222 may have an elliptical shape, or a rectangular shape having a first width D1 and a second width D2. The first width D1 and the second width D2 may be varied depending on the proportion of radicals to be transferred to the substrate W, etc. In other words, an operator may optionally install the upper baffle 210 and the lower baffle 220 formed with the holes 212, 222 having various sizes, shapes, and the like in the substrate processing apparatus 10, depending on the required values for processing the substrate W.

The drive unit 230 changes the relative position of the upper baffle 210 and the lower baffle 220. By moving either the upper baffle 210 or the lower baffle 220 relative to the other, the drive unit 230 may change the degree of overlap of the upper hole 212 and the lower hole 222.

The drive unit 230 may include a motor. The drive unit 230 may be a servo motor. The drive unit 230 may be connected to one side of the lower baffle 220 to rotate the lower baffle 220, as illustrated in FIG. 3. When the drive unit 230 rotates the lower baffle 220, the degree of overlap of the upper hole 212 formed in the upper baffle 210 and the lower hole 222 formed in the lower baffle 220, in other words, the hole pattern of the baffle assembly 200, may change. As the hole pattern of the baffle assembly 200 changes, the hole size of the baffle assembly 200, that is, the size of the hole formed by the overlap of the upper hole 212 and the lower hole 222 when viewed from above, may change.

As such, in the process in which the plasma generated in the plasma generation space 122 enters the treatment space 112 through the holes 212, 222 formed in the upper baffle 210 and the lower baffle 220, the degree of overlap of the upper holes 212 and the lower holes 222, i.e., changes in the hole pattern and hole size of the baffle assembly 200, may vary the rate at which ions contained in the plasma pass through the baffle assembly 200 and enter the treatment space 112.

The support unit 300 may support the substrate W. The support unit 300 may support the substrate W in the treatment space 112. The support unit 300 may include an electrostatic chuck 310, and a lower electrode 320.

The electrostatic chuck 310 may chuck the substrate W. The electrostatic chuck 310 may have a dielectric plate 311 and an electrostatic electrode 312. The dielectric plate 311 may provide a seating surface on which the substrate W is placed. The dielectric plate 311 may have an electrostatic electrode 312 buried within the dielectric plate 311. The electrostatic electrode 312 may be applied with power from a chucking power source (not illustrated), which may be a DC power source, to generate electrostatic force for chucking the substrate W.

The lower electrode 320 may be disposed below the electrostatic chuck 310. The lower electrode 320 may be made of a material including metal. The lower electrode 320 may be connected to the lower electrode unit 300, which will be described later. The lower electrode 23 may have a flow path 321 formed in it. A cooling fluid, such as a coolant or cooling gas, may flow in the flow path 321. A fluid supply line 322 may be connected to one end of the flow path 321 to supply cooling fluid, and a fluid recovery line 323 may be connected to the other end to recover cooling fluid.

The lower power unit 400 may apply high frequency RF power to the lower electrode 320. The lower power unit 400 may apply bias power to the lower electrode 320. The lower power unit 400 may include a second power source 410 and a second matcher 420. The second power source 410 may be a bias power source. The second power source 410 may apply second power having a second frequency to the lower electrode 320. The second matcher 420 may perform impedance matching to ensure that power from the second power source 410 is effectively delivered to the lower electrode 320.

RF power applied by the lower power unit 400 may control the flow of plasma P including at least one of ions, electrons, and radicals flowing into the treatment space 112 to improve treatment efficiency for the substrate W. Additionally, RF power applied by the lower power unit 400 may excite process gas supplied to the treatment space 112 to generate the plasma P.

The source unit 500 may generate the plasma P in the plasma generation space 122. The source unit 500 may generate plasma P in the plasma generation space 122 by exciting process gas supplied by the gas supply unit 600 described later.

The source unit 500 may include a coil 510, a first power source 520, and a first matcher 530.

The coil 510 may be configured to surround the plasma generation chamber 120. The coil 510 may be provided on an exterior side of the plasma generation chamber 120. The number of windings of the coil 510 wrapped around the plasma generation chamber 120 may vary depending on the strength of the electric field required in the treatment space 122. The coil 510 may receive power from the first power source 520 and may create an electric field in the plasma generation space 122. The electric field formed in the plasma generation space 122 may excite the process gas to generate plasma P. The coil 510 may also be referred to as the top electrode.

The first power source 520 may apply RF power to the coil 510. The first power source 520 may apply first power to the coil 510 having a first frequency that is a different frequency from the second frequency described above. The first frequency may be a higher frequency than the second frequency. The first power source 520 may be a source power source. The first matcher 530 may perform impedance matching to ensure that power from the first power source 520 is effectively delivered to the coil 510.

Although not illustrated, the substrate processing apparatus 10 may further include an impedance control unit, and the impedance control unit may be configured to form a resonant circuit with respect to the first frequency and the second frequency. The impedance control unit may include a sensor S, an inductor L1, a first capacitor C1, and a second capacitor C2.

The gas supply unit 600 may supply process gas to the plasma generation space 122 and/or the treatment space 112. The gas supply unit 600 may include a gas supply source 610, and a gas supply line 620. The gas supply source 610 may supply and/or store process gas. The gas supply line 620 may be connected to an upper portion of the plasma generation chamber 120. The gas supply source 610 may supply process gas to the plasma generation space 122 via the gas supply line 620.

A majority of the process gas supplied to the plasma generation space 122 may be excited to the plasma P state by the source unit 500. A portion of the process gas may not be excited in the plasma generation space 122 and may enter the treatment space 112. The process gas introduced into the treatment space 112 may be excited to the plasma P state by the lower power unit 400.

The exhaust device 700 may exhaust the treatment space 112. The exhaust device 700 may be connected to a lower portion of the treatment chamber 110. The exhaust device 700 may be a pump. An exhaust hole (not illustrated) may be formed in the lower portion of the treatment chamber 110, and the exhaust device 700 may exhaust the treatment space 112 through the exhaust hole. The exhaust device 700 may depressurize the treatment space 112. Process by-products or impurities in the treatment space 112 may be discharged to the outside of the treatment chamber 110 through the exhaust device. The exhaust device 700 may depressurize the treatment space 112, creating a downdraft flow in the plasma generation space 122 and/or the treatment space 112. The exhaust device 700 may help the pressure in the treatment space 112 reach a pressure close to a vacuum while the process is being performed.

The controller 900 may control the substrate processing apparatus 10. The controller 900 may control the configurations of the substrate processing apparatus 10. For example, the controller 900 may generate control signals to control the support unit 300, the lower power unit 400, the source unit 500, the gas supply unit 600, and the exhaust device 700.

The controller 900 may include a process controller formed of a microprocessor (computer) that executes the control of the substrate processing apparatus 10, a user interface formed of a keyboard in which an operator performs a command input operation or the like in order to manage the substrate processing apparatus 10, a display for visualizing and displaying an operation situation of the substrate processing apparatus 10, and the like, and a storage unit storing a control program for executing the process executed in the substrate processing apparatus 10 under the control of the process controller or a program, that is, a processing recipe, for executing the process in each component according to various data and processing conditions. Further, the user interface and the storage unit may be connected to the process controller. The treatment recipe may be memorized in a storage medium in the storage unit, and the storage medium may be a hard disk, and may also be a portable disk, such as a CD-ROM or a DVD, or a semiconductor memory, such as a flash memory.

The substrate processing apparatus 10 may generate plasma P to process the substrate W, for example to perform an etch process or a strip process to remove a film formed on the substrate W.

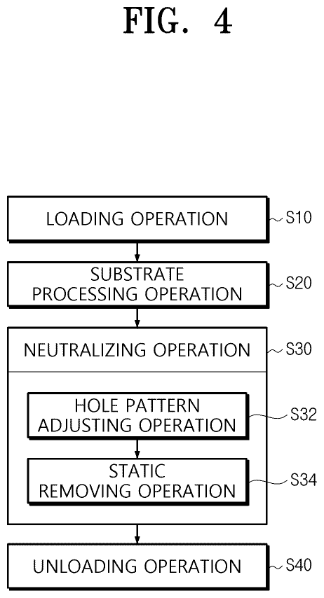

FIG. 4 is a flow chart illustrating an exemplary embodiment of a method of processing a substrate using the substrate processing apparatus of FIG. 3.

Referring to FIGS. 3 and 4, a substrate processing method according to the exemplary embodiment of the present invention may include a loading operation S10, a substrate processing operation S20, a neutralizing operation S30, and an unloading operation S40, in which the neutralizing operation S30 may include a hole pattern adjusting operation S32 and a static removing operation S34.

In the loading operation S10, the substrate W may be loaded into the treatment space 112 by a transfer robot (not illustrated). The substrate W loaded into the treatment space may be placed on the support unit 300. The electrostatic chuck 310 may chuck the substrate W by generating electrostatic force.

When the loading operation S10 ends and the substrate W is loaded onto the support unit 300, a processing operation S20 is performed.

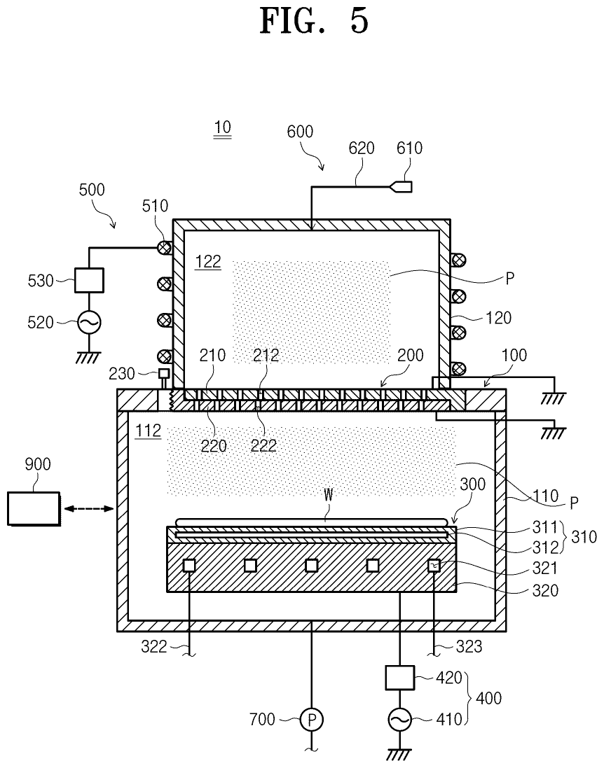

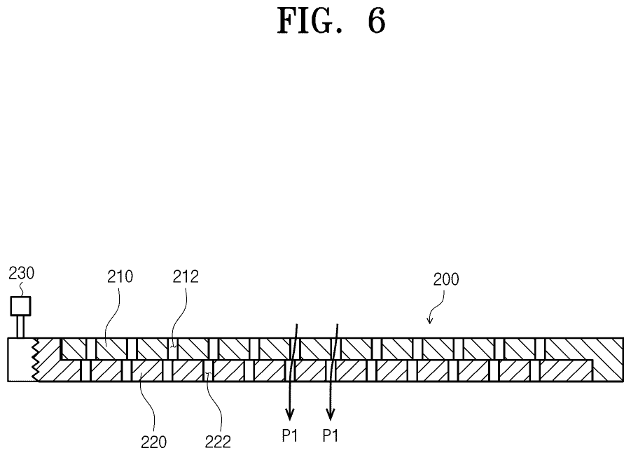

In the processing operation S20, the substrate W is treated by supplying plasma P to the treatment space 112. FIG. 5 is a diagram schematically illustrating the case where the substrate processing apparatus of FIG. 3 performs the substrate processing operation of FIG. 4, and FIG. 6 is an enlarged view of a baffle assembly of FIG. 5.

Referring to FIGS. 5 and 6, the gas supply unit 600 may supply process gas to the plasma generation space 122, and the source unit 500 may excite the process gas to generate plasma P. The first power source 520 of the source unit 500 may apply second power having a first frequency (e.g., 13.56 MHz) to the coil 510. The plasma P generated in the plasma generation space 122 may include ions, electrons, and radicals. Of these, radicals may largely pass through the baffle assembly 200 and enter the treatment space 112. Additionally, process gas that is not excited to the plasma P state in the plasma generation space 122 may pass through the baffle assembly 200 and enter the treatment space 112.

In the substrate processing operation S20, the controller 900 controls the baffle assembly 200 such that the degree of overlap of the upper hole 212 and the lower hole 222 is maintained at a first degree of overlap. Maintaining the degree of overlap of the upper hole 212 and the lower hole 222 at the first degree of overlap may refer to a condition where, when viewed from above, the area of the communicating passageway between the plasma generation space 122 and the treatment space 112 is relatively narrower than when the upper hole 212 and the lower hole 222 are partially overlapped and at a second degree of overlap described later. As seen above, when the degree of overlap of the upper hole 212 formed in the upper baffle 210 and the lower hole 222 formed in the lower baffle 220 is at the first degree of overlap degree, or in other words, when the hole pattern of the baffle assembly 200 is at the first degree of overlap, the hole size of the baffle assembly 200 may be smaller than the size of the sheath around the holes 212, 222 of the baffle assembly 200. That is, the diameter of the hole formed by the overlap of the upper hole 212 and the lower hole 222 of the baffle assembly 200 may be shorter than the length of the sheath around the hole. When the plasma P generated in the plasma generation space 122 passes through the baffle assembly 200 and is supplied into the treatment space 112, the ions contained in the plasma P are trapped, with most of them not passing through the baffle assembly 200 due to the small size of the holes, and first plasma P1 is supplied into the treatment space 112.

The radicals introduced into the treatment space 112 may remove the film on the substrate W. In addition, the process gas entering the treatment space 112 may be partially excited into plasma P by an electric field formed by the second power source 410, which is a bias power source. The second power source 410 may apply second power having a second frequency (e.g., 2 MHz) to the lower electrode 320.

The plasma P removes the film on the substrate W. As described above, the film on the substrate W may include at least one of a first film (photoresist thin film) or a second film (hardmask thin film), as illustrated in FIGS. 1 and 2.

During the treatment of the substrate using the plasma in the processing operation S20, a negative charge is accumulated on the substrate W and a negative voltage is applied because the mobility of electrons in the treatment space 112 is faster than that of ions. The negative voltage applied at this time is called a DC self bias.

The processing operation S20 ends, the second power source 410 is switched off and the generation of plasma in the treatment space 112 is stopped. Even though no RF signal is flowing to the lower electrode 320, strong attractive force due to a voltage difference is formed between the substrate W and the lower electrode 320 because of the accumulation of negative charge on the substrate W. When the substrate W is unloaded from the support unit 300 immediately after the end of the processing operation S20, the substrate may be damaged due to the attraction between the substrate W and the lower electrode 320 of the support unit 300. Therefore, after the processing operation S20, a neutralizing operation S30 is performed to remove the residual charge accumulated on the substrate W.

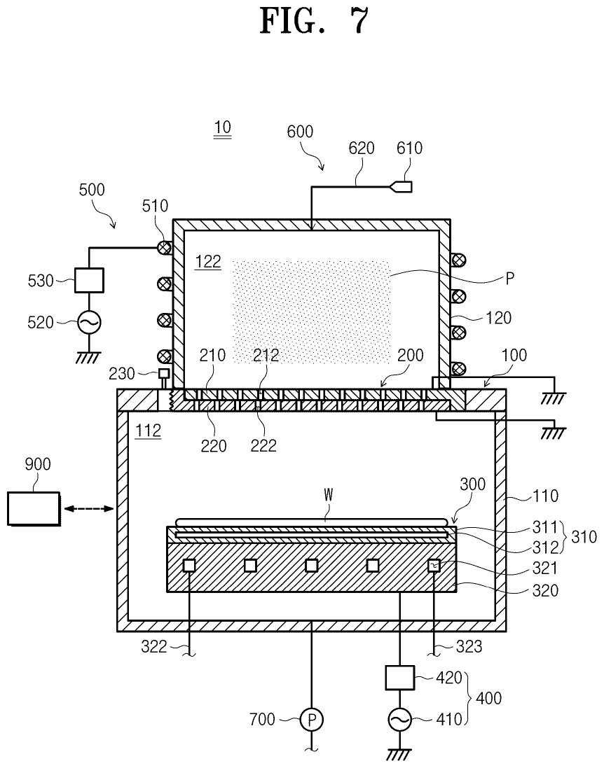

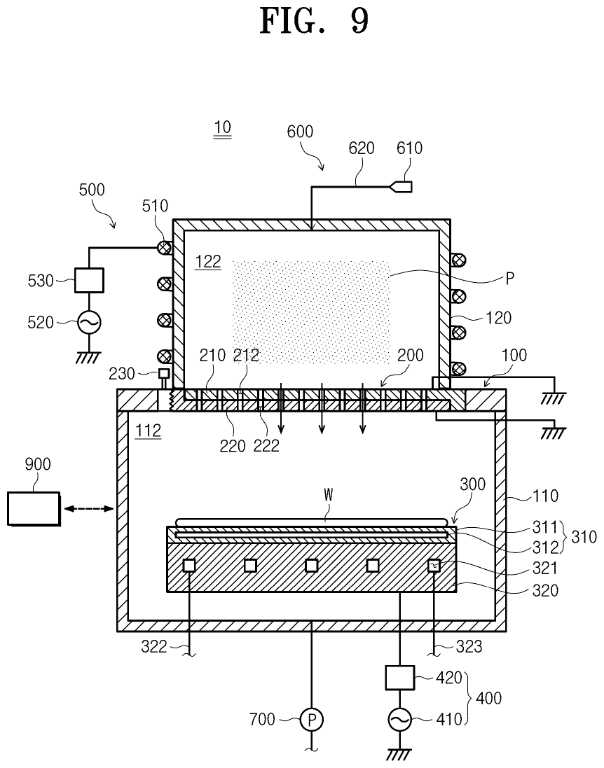

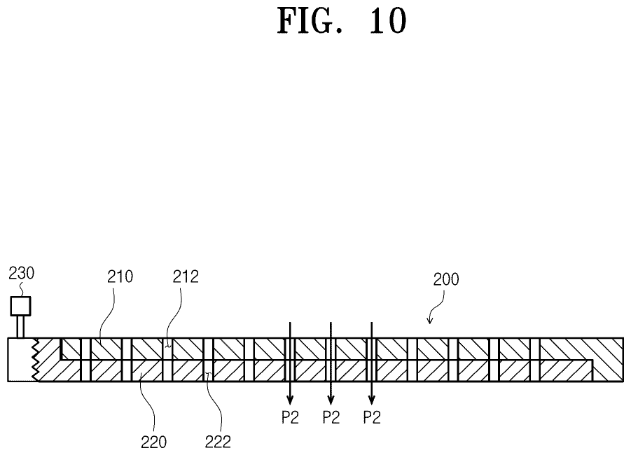

FIGS. 7 to 9 are diagrams schematically illustrating what the substrate processing apparatus of FIG. 3 looks like when performing the neutering operation of FIG. 4, and FIG. 10 is an enlarged view of the baffle assembly of FIG. 9.

Hereinafter, the neutralizing operation S30 will be described with reference to FIGS. 7 to 10.

Referring to FIG. 7, before the neutralizing operation S30 proceeds, the second power source 410 is switched off to stop the generation of plasma in the treatment space 112. Then, during the neutralizing operation S30, the hole pattern adjusting operation S32 is performed.

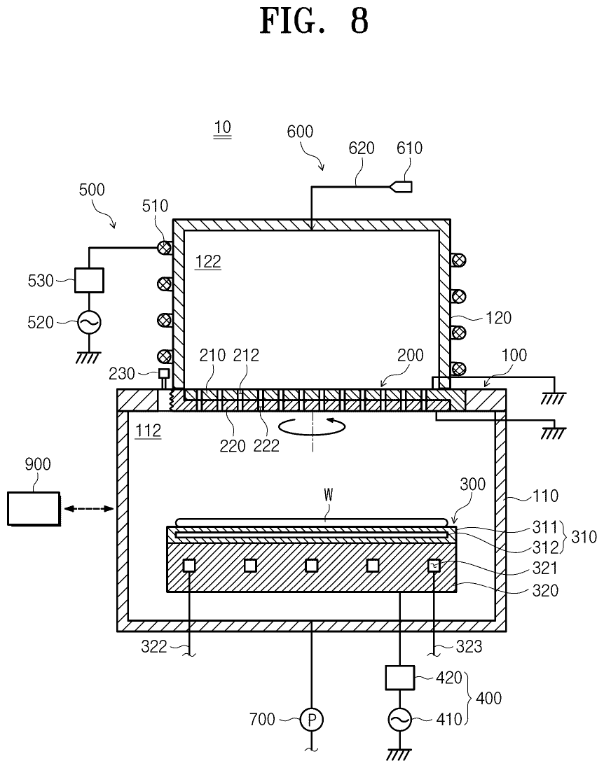

As illustrated in FIG. 8, in the hole pattern adjusting operation S32, the drive unit 230 may rotate the lower baffle 220 to change the degree of overlap of the upper holes 212 formed in the upper baffle 210 and the lower holes 222 formed in the lower baffle 220, in other words, the hole pattern of the baffle assembly 200. The drive unit 230 changes the hole pattern of the baffle assembly 200 from a first degree of overlap to a second degree of overlap. In a state where the hole pattern of the baffle assembly 200 is in the second degree of overlap, the upper hole 212 and the lower hole 222 have a higher degree of overlap than in a state where the hole pattern of the baffle assembly 200 is in the first degree of overlap. In other words, the state in which the degree of overlap of the upper hole 212 and the lower hole 222 is at the second degree of overlap may refer to a case in which the area of the passageway communicating between the plasma generation space 122 and the treatment space 112 is relatively larger than in the state in which the degree of overlap of the upper hole 212 and the lower hole 222 is at the first degree of overlap. For example, when the degree of overlap of the upper hole 212 and the lower hole 222 is changed to the second degree of overlap, the upper hole 212 and the lower hole 222 may be fully overlapped and appear to be a single hole when viewed from above.

When the degree of overlap of the upper hole 212 formed in the upper baffle 210 and the lower hole 222 formed in the lower baffle 220 is at the second degree of overlap, or in other words, when the hole pattern of the baffle assembly 200 is at the second degree of overlap, the hole size of the baffle assembly 200 may be larger than the size of the sheath around the holes 212, 222 of the baffle assembly 200. That is, the diameter of the hole formed by the overlap of the upper hole 212 and the lower hole 222 of the baffle assembly 200 may be larger than the length of the sheath around the hole. When the plasma P generated in the plasma generation space 122 passes through the baffle assembly 200 and is supplied into the treatment space 112, many of the ions contained in the plasma P pass through the baffle assembly 200, and second plasma P2 is supplied into the treatment space 112, as illustrated in FIGS. 9 and 10.

As described above, the second plasma P2 supplied to the treatment space 112 in the neutralizing operation S30 is provided with a higher proportion of ions contained in the plasma than the first plasma P1 supplied to the treatment space 112 in the substrate processing operation S20. That is, the proportion of ions to radicals in the second plasma P2 supplied into the treatment space 112 is provided to be higher than the proportion of ions to radicals in the first plasma P1 supplied into the treatment space 112. This is because the size of the hole pattern of the baffle assembly 200 in the neutralizing operation S30 is larger than the size of the hole pattern of the baffle assembly 200 in the substrate processing operation S20, and is larger than the length of the sheath around the holes of the baffle assembly 200, making it easier for ions to pass through the baffle assembly 200 in the neutralizing operation S30.

At the end of the hole pattern adjusting operation S32, a static removing operation S34 is performed.

In the static removing operation S34, the accumulated charge on the substrate W may be discharged. Specifically, ions (particularly positive ions) contained in the second plasma P2 supplied to the treatment space 112 may neutralize the substrate W and rapidly discharge the charge on the substrate W. At the end of the static removing operation S34, the gas supply unit 600 stops supplying process gas, the first power source 520 is switched off to stop the generation and supply of plasma, and the neutralizing operation S30 ends.

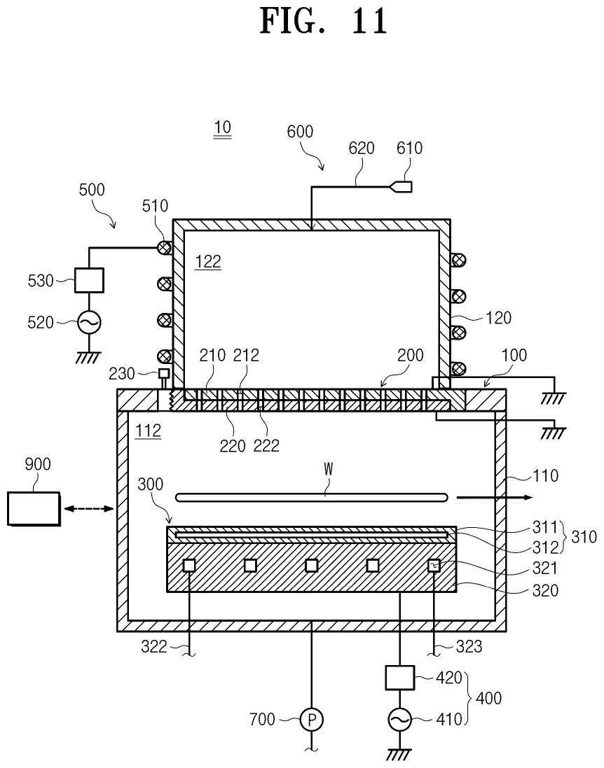

When the neutralizing operation S30 ends, the unloading operation S40 is performed. FIG. 11 is a diagram schematically illustrating the case where the substrate processing apparatus of FIG. 3 performs the unloading operation of FIG. 4.

In the unloading operation S40, the electrostatic chuck 310 may dechuck the substrate W, and the substrate W may be lifted from the support unit 300 and unloaded from the treatment space 112.

As described above, by performing the neutralizing operation S30 to discharge the charge accumulated on the substrate W by adjusting the hole pattern of the baffle assembly 200 and selectively passing ions through it prior to unloading the substrate W from the support unit 300 after the processing operation S20, damage to the substrate W due to electrical attraction between the substrate W and the electrostatic chuck 310 during the unloading of the substrate W may be minimized.

In addition, the drive unit 230 may switch the degree of overlap of the upper holes 212 and lower holes 222 between the first degree of overlap and the second degree of overlap by changing the relative position of the upper baffle 210 or the lower baffle 220, adjust the proportion of ions contained in the plasma passing through the baffle assembly by varying the hole pattern and hole size of the baffle assembly 200, and neutralize the substrate by rapidly discharging the charge accumulated on the substrate after processing the substrate with the plasma.

In the above example, it is illustrated and described that when the upper hole 212 and the lower hole 222 are in the second degree of overlap, the upper hole 212 and the lower hole 222 may be fully overlapped and appear to be a single hole when viewed from above, but the present invention is not limited thereto. It is sufficient that the second degree of overlap state described above is any state in which the upper hole 212 and the lower hole 222 have a higher degree of overlap than the first degree of overlap in the substrate processing operation S20.

In the examples described above, the present invention has been described based on the case where the upper electrode is the coil 510, but is not limited thereto. For example, the upper electrode may be provided as an electrode plate having a plate shape.

In the exemplary embodiment described above, not only the plasma generation space 122, but also the treatment space 112 is illustrated and described as being excited with plasma P by an electric field formed by the second power source 410, which is a bias power source. For example, the plasma P may be excited only in the plasma generation space 122 and introduced into the treatment space 112 through the baffle assembly 200.

In the exemplary embodiment described above, the drive unit 230 is illustrated and described as being connected to one side of the lower baffle 220 to rotate the lower baffle 220, but the present invention is not limited thereto. The drive unit 230 may be connected to one side of the upper baffle 210 to rotate the upper baffle 210, or may be connected to one side of each of the upper baffle 210 and the lower baffle 220 to rotate both the upper baffle 210 and the lower baffle 220.

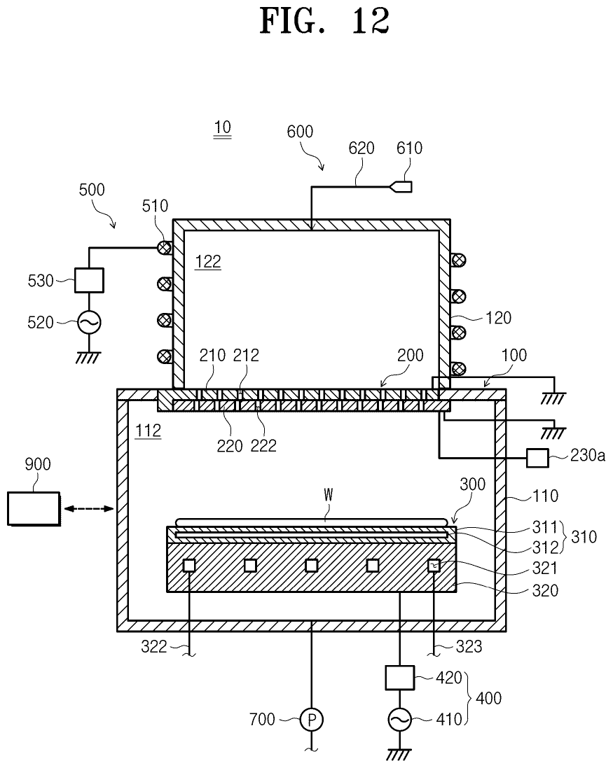

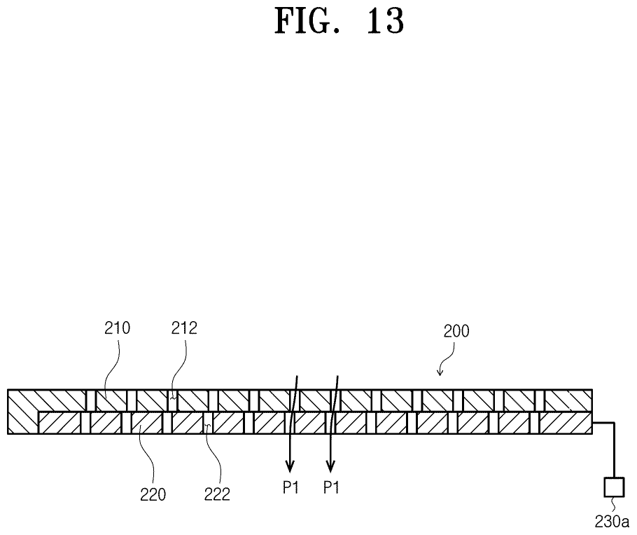

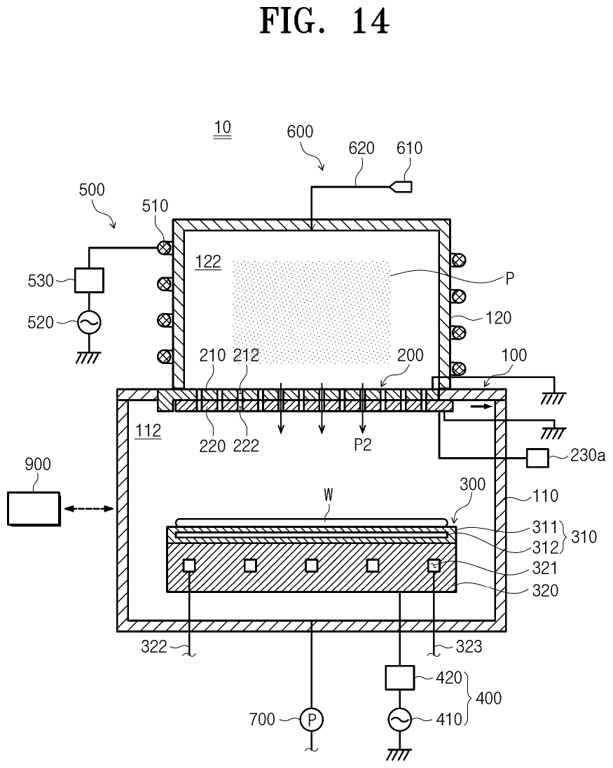

FIGS. 12 to 14 are diagrams illustrating a substrate processing apparatus according to another exemplary embodiment of the present invention. In the above described exemplary embodiment, the drive unit 230 is illustrated and described as rotating the lower baffle 220 to switch the hole pattern of the baffle assembly 200 between the first degree of overlap and the second degree of overlap, but in the substrate processing apparatus according to another exemplary embodiment of FIGS. 12 to 14, the drive unit 230a may switch the hole pattern of the baffle assembly 200 between the first degree of overlap and the second degree of overlap by horizontally moving at least one baffle between the upper baffle 210 and the lower baffle 220.

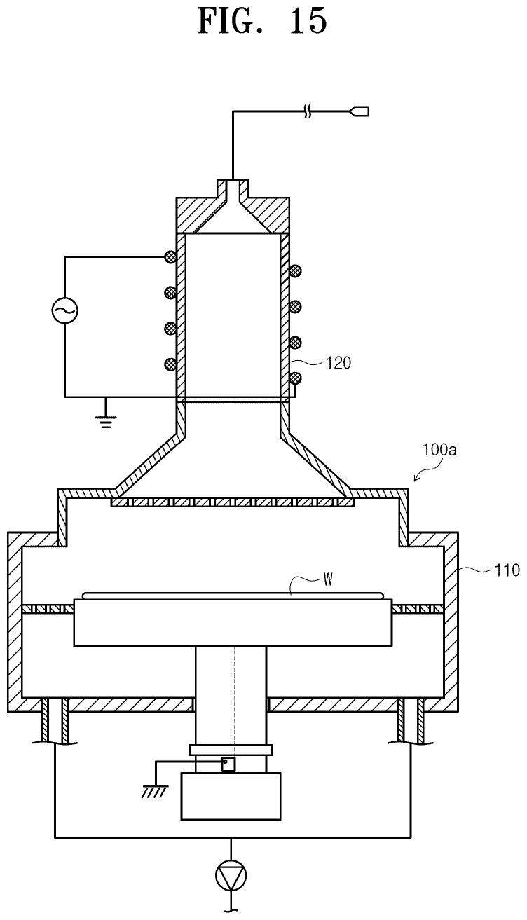

In the exemplary embodiment described above, the chamber 100 is illustrated and described as including the treatment chamber 110 and the plasma generation chamber 120, and the baffle assembly 200 is illustrated and described as being installed between the treatment chamber 112 and the plasma generation chamber 122, but the present invention is not limited thereto. The chamber 100 may be applied to a variety of devices that treat the substrate W with plasma. For example, as illustrated in FIG. 15, the chamber 100 may be provided to include an adapter configuration, which is a space in which plasma flows between the treatment chamber 110 and the plasma generation chamber 120.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A method of processing a substrate, the method comprising:
a substrate processing operation of supplying first plasma generated in a plasma generation space through a baffle assembly into a treatment space, and processing a substrate supported on a support unit within the treatment space by using the first plasma; and
a neutralizing operation of, after the substrate processing operation, while the substrate is supported on the support unit, supplying second plasma generated in the plasma generation space through the baffle assembly into the treatment space to remove residual charges on the substrate.

2. The method of claim 1, wherein a proportion of ions to radicals in the second plasma supplied into the treatment space is higher than a proportion of ions to radicals in the first plasma supplied into the treatment space.

3. The method of claim 1, wherein the baffle assembly includes:
an upper baffle formed with a plurality of upper holes penetrating in an upward and downward direction; and
a lower baffle stacked with the upper baffle and formed with a plurality of lower holes penetrating in the upward and downward direction, and
in the substrate processing operation, the upper hole and the lower hole are maintained in a first degree of overlap when viewed from above,
in the neutralizing operation, the upper hole and the lower hole are maintained in a second degree of overlap when viewed from above, and
the second degree of overlap is a higher degree of overlap of the upper hole and the lower hole compared to the first degree of overlap.

4. The method of claim 3, wherein the degree of overlap of the upper hole and the lower hole is switched between the first degree of overlap and the second degree of overlap by changing a relative position of the upper baffle or the lower baffle.

5. The method of claim 4, wherein the relative position of the upper baffle or the lower baffle is changed by rotating at least one of the upper baffle and the lower baffle.

6. The method of claim 1, wherein the substrate processing operation is a process of removing a thin film on the substrate by using plasma.

7. The method of claim 6, wherein the thin film is a hard mask.

8. The method of claim 1, wherein the support unit includes an electrostatic chuck,
the method further comprises:
a loading operation of placing the substrate onto the support unit prior to the substrate processing operation; and
an unloading operation of lifting the substrate from the support unit after the neutralizing operation, and
the loading operation is an operation of chucking the substrate onto the electrostatic chuck, and
the unloading operation is an operation of dechucking the substrate from the electrostatic chuck.

9. The method of claim 1, wherein the support unit further includes a high frequency power source applying high frequency power,
in the substrate processing operation, the high frequency power source generates plasma in the treatment space, and
after the substrate processing operation ends, the high frequency power source is switched off and the neutralizing operation is performed.

10. The method of claim 1, wherein the plasma generating space is supplied with treatment gas to generate plasma, and
the treatment gas supplied to the plasma generation space in the substrate processing operation and in the neutralizing operation is the same gas.

11. A method of processing a substrate, the method comprising:
a loading operation of placing a substrate onto a support unit in a treatment space;
a substrate processing operation of, after the loading operation, supplying first plasma generated in the plasma generation space through a baffle assembly into the treatment space and treat the substrate with the first plasma;
a neutralizing operation of, after the substrate processing operation, while the substrate is supported on the support unit, supplying second plasma generated in the plasma generation space through the baffle assembly into the treatment space to remove residual charges on the substrate; and
an unloading operation of, after the neutralizing operation, lifting the substrate from the support unit,
wherein a proportion of ions to radicals in the second plasma supplied into the treatment space is higher than a proportion of ions to radicals in the first plasma supplied into the treatment space.

12. The method of claim 11, wherein the support unit further includes a high frequency power source applying high frequency power,
in the substrate processing operation, the high frequency power source generates plasma in the treatment space, and
after the substrate processing operation ends, the high frequency power source is switched off and the neutralizing operation is performed.

13. The method of claim 11, wherein the baffle assembly includes:
an upper baffle formed with a plurality of upper holes penetrating in an upward and downward direction; and
a lower baffle stacked with the upper baffle and formed with a plurality of lower holes penetrating in the upward and downward direction, and
in the substrate processing operation, the upper holes and the lower holes are maintained in a first degree of overlap when viewed from above,
in the neutralizing operation, the upper hole and the lower hole are maintained in a second degree of overlap when viewed from above, and
the second degree of overlap is a higher degree of overlap of the upper hole and the lower hole compared to the first degree of overlap.

14. The method of claim 13, wherein the degree of overlap of the upper hole and the lower hole is switched between the first degree of overlap and the second degree of overlap by changing a relative position of the upper baffle or the lower baffle.

15. The method of claim 14, wherein the relative position of the upper baffle or the lower baffle is changed by rotating at least one of the upper baffle or the lower baffle.

16. An apparatus for processing a substrate, the apparatus comprising:
a treatment chamber having a treatment space for processing a substrate therein;
a support unit for supporting a substrate in the treatment space;
a plasma generation chamber provided outside the treatment chamber and having a plasma generation space for generating plasma from treatment gas;
a baffle assembly disposed between the treatment space and the plasma generation space; and
a controller,
wherein the baffle assembly includes:
an upper baffle formed with a plurality of upper holes penetrating in an upward and downward direction;
a lower baffle stacked with the upper baffle and formed with a plurality of lower holes penetrating in the upward and downward direction; and
a drive unit for changing a relative position of the upper baffle and the lower baffle, and
the controller controls the drive unit to sequentially perform
a substrate processing operation of processing the substrate by supplying first plasma into the treatment space in a state where the upper hole and the lower hole are maintained in a first degree of overlap when viewed from above, and
a neutralizing operation of, after the substrate processing operation, supplying second plasma into the treatment space in a state where the upper hole and the lower hole are maintained in a second degree of overlap to remove a residual charge on the substrate, and
the second degree of overlap is a higher degree of overlap of the upper hole and the lower hole compared to the first degree of overlap.

17. The apparatus of claim 16, wherein the drive unit rotates at least one of the upper baffle and the lower baffle to adjust a hole pattern and a hole size of the baffle assembly.

18. The apparatus of claim 16, further comprising:
a high frequency power source for applying high frequency power to the support unit.

19. The apparatus of claim 16, wherein in the substrate processing operation, the hole size of the baffle assembly is smaller than a size of a sheath around the hole of the baffle assembly.

20. The apparatus of claim 16, wherein in the neutralizing operation, the controller adjusts the size of the hole of the baffle assembly to be greater than a size of a sheath around the hole in the baffle assembly.
